(19) United States
(12) Patent Application Publication
(10) Pub. No.: US 2025/0318067 A1
(43) Pub. Date: Oct. 9, 2025

(54) Computer Rack Power Supply Redundancy

(71) Applicant: Microsoft Technology Licensing, LLC, Redmond, WA (US)

(72) Inventors: Andrew SULLIVAN, Greeley, CO (US); Scot HEATH, Fort Collins, CO (US)

(73) Assignee: Microsoft Technology Licensing, LLC, Redmond, WA (US)

(21) Appl. No.: 18/629,635

(22) Filed: Apr. 8, 2024

(51) Int. Cl. H05K 7/14; G06F 1/26

(52) U.S. Cl. CPC H05K 7/1492; G06F 1/263; H05K 7/1498

(57) ABSTRACT

The description relates to ensuring redundancy of computer rack power supplies. One example can include a rack holding multiple computers and first and second leads associated with the rack. The example can also include a status component positioned in the rack and receiving power from the first and second leads to power the multiple computers. The status component configured to compare power received from the first lead and power received from the second lead to determine whether the first lead and the second lead are supplying power from two different power sources or from a single power source.

### BACKGROUND

To obtain desired computer resources and densities, large numbers of computers tend to be physically located together in multiple adjacent computer racks. Reducing down-time (e.g., ensuring the reliability) of these computers is extremely important. One source of downtime is power supply failures.

### SUMMARY

This patent relates to ensuring redundancy of computer rack power supplies. One example can include a rack holding multiple computers and first and second leads connected to the rack. The example can also include a status component positioned in the rack and receiving power from the first and second leads to power the multiple computers. The status component is configured to compare power received from the first lead and power received from the second lead to determine whether the first lead and the second lead are supplying power from two different power sources or from a single power source.

This summary is intended to provide a quick introduction to some of the present concepts and is not intended to be limiting or all inclusive.

### BRIEF DESCRIPTION OF THE DRAWINGS

The accompanying drawings illustrate implementations of the concepts conveyed in the present patent. Features of the illustrated implementations can be more readily understood by reference to the following description taken in conjunction with the accompanying drawings. Like reference numbers in the various drawings are used wherever feasible to indicate like elements. Further, the left-most numeral of each reference number conveys the figure and associated discussion where the reference number is first introduced. Where space permits elements and their corresponding numerical designators are both shown on the drawings to aid the reader, otherwise only numerical designators are shown.

FIGS. 1A-1E, 2, and 6 show example computer rack power supply redundancy checking systems in accordance with some implementations of the present concepts.

FIGS. 3-5 show schematic diagrams of example computer rack power supply redundancy systems in accordance with some implementations of the present concepts.

FIG. 7 shows an example flowchart for computer rack power supply redundancy verification in accordance with some implementations of the present concepts.

### DETAILED DESCRIPTION

The present concepts relate to enhancing reliability and/or decreasing downtime of computers positioned in a rack, such as in a datacenter. To achieve desired compute power and density, multiple computers tend to be physically located together in computer racks. Many of these racks of computers are positioned in physical proximity to one another. All these computers require large amounts of power to operate. The power can be obtained from power supply buses that extend proximate to the racks. Individual buses receive individual power supplies or power feeds. Leads or whips can connect the buses to the computer racks and hence to the computers.

In order to increase reliability, redundant power feeds, power supply buses, and leads can be connected to each rack. However, if the redundant buses and/or leads are not properly connected, the power feed redundancy is lost and reliability suffers. The present concepts provide a technical solution that automatically checks that the racks are receiving redundant power feeds and thus ensures that the designed redundancy is actually achieved. The technical solution involves adding a unique signal to each individual power feed. The term ‘unique signal’ means that the unique signal has one or more properties that are distinguishable from properties of other unique signals and the properties of the power feed. For example, the property could relate to frequency. The power feed could have a 60 hertz frequency while a first unique signal has a 5 megahertz frequency and a second unique signal has a 50 megahertz frequency, for example. This configuration would allow the unique signals to be distinguished from one another and the power feeds.

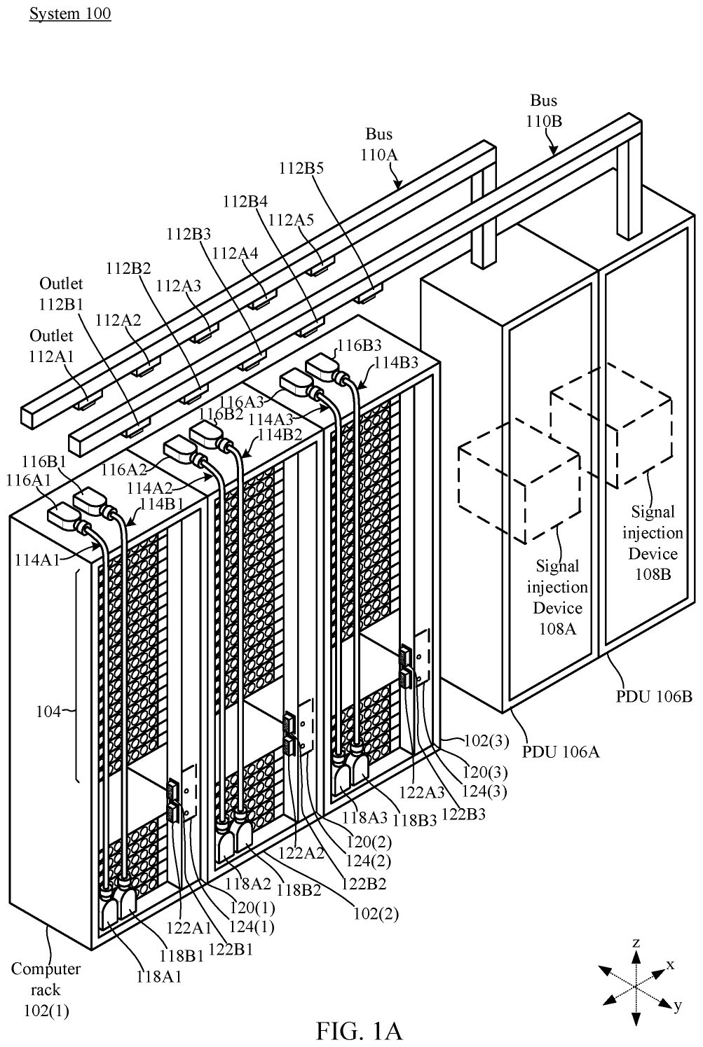

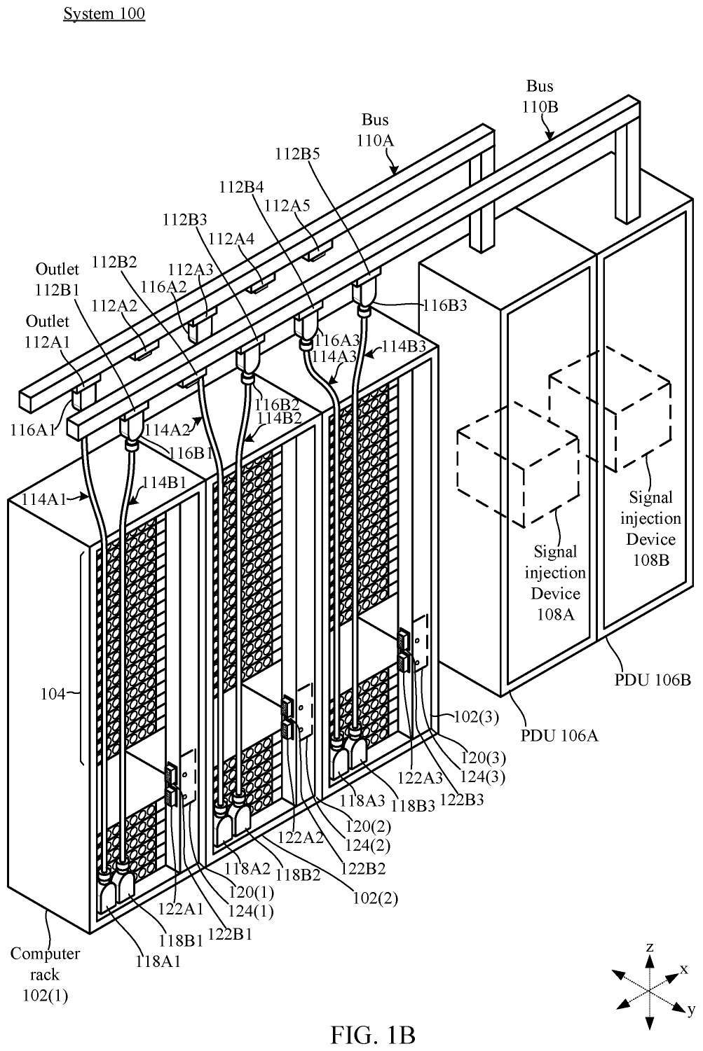

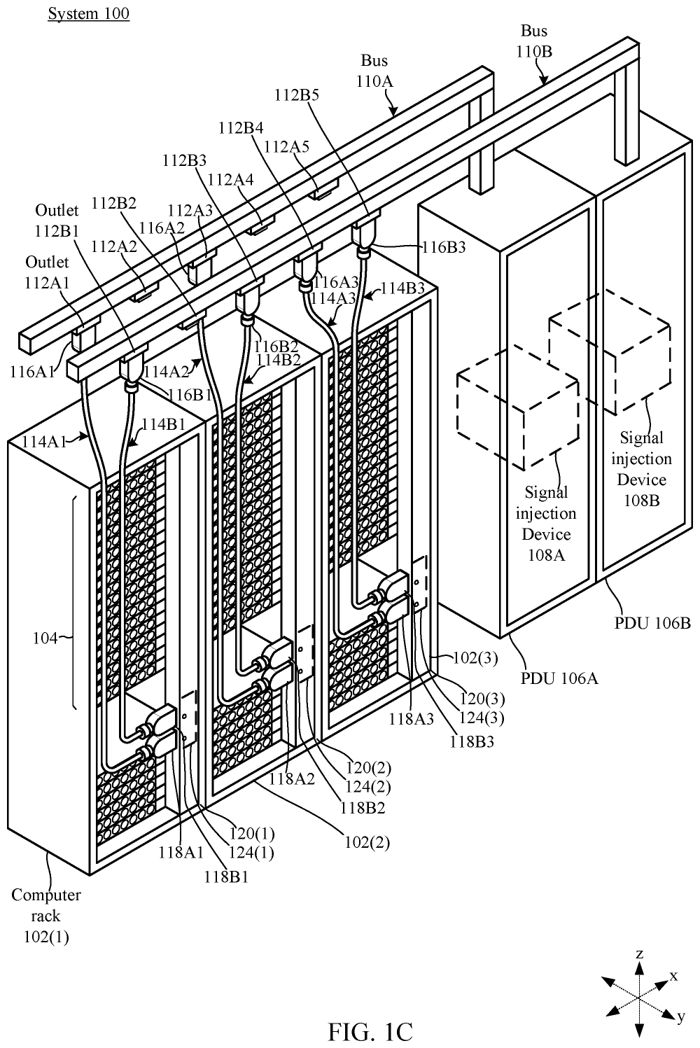

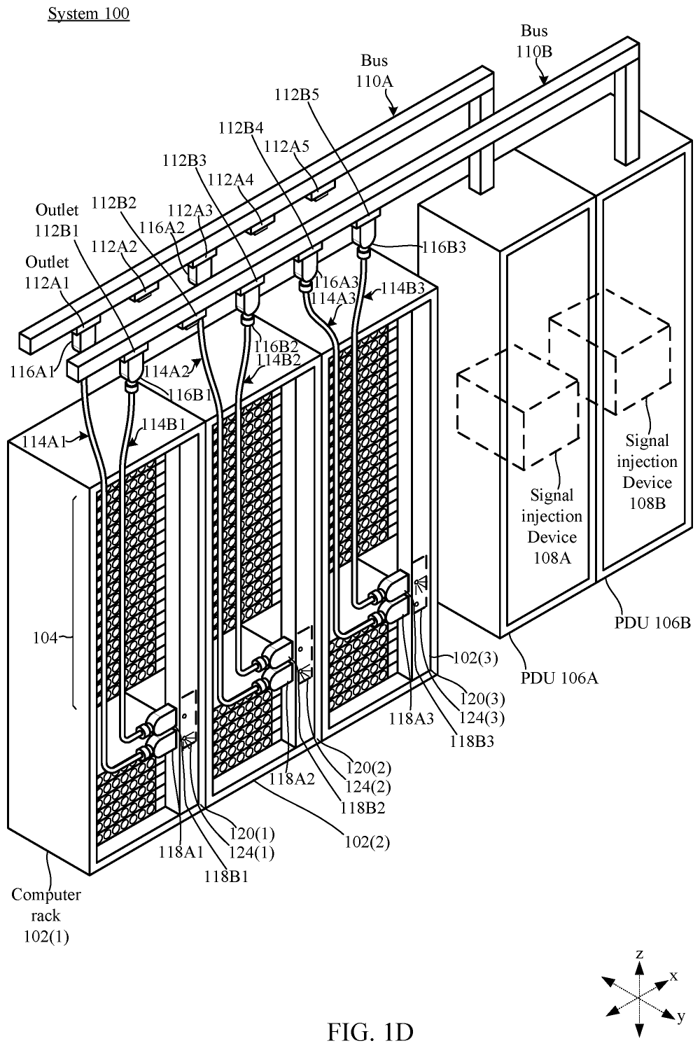

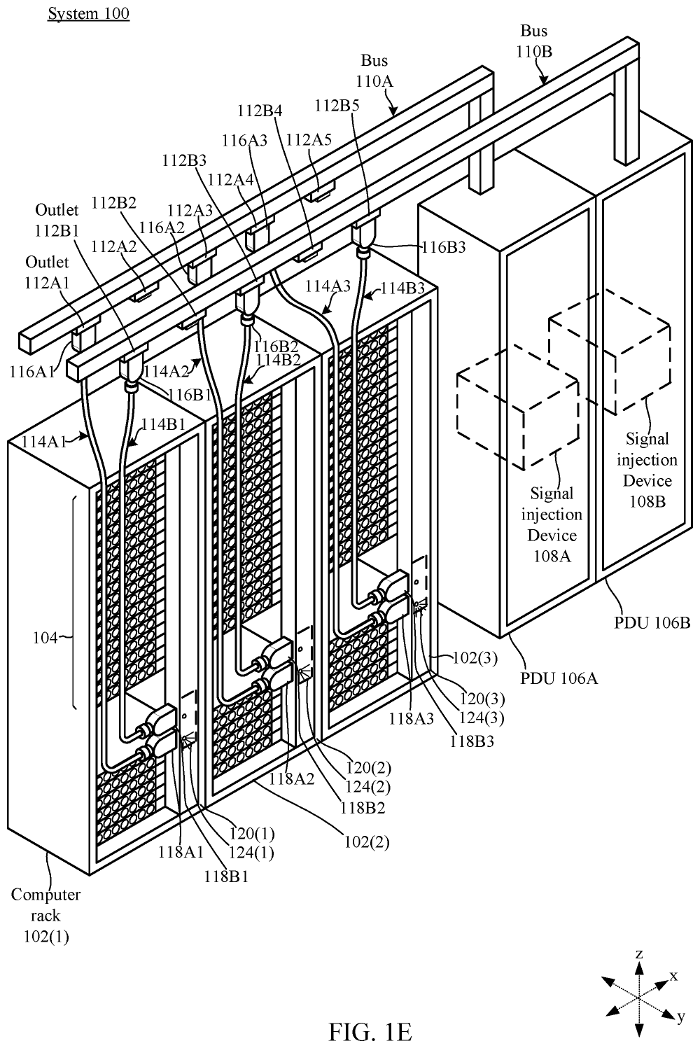

The rack receives the supplied power feeds and examines the received power feeds. Detection of a first unique signal in a first received power feed and a second unique signal in a second received power feed confirms that power is in fact being received from two distinct power feeds. Detecting the two different unique signals confirms the desired power feed redundancy for the rack has been achieved (e.g., is occurring). An example scenario that elaborates these concepts is described below relative to FIGS. 1A-1E.

FIGS. 1A-1E collectively show an example system 100. The system 100 includes computer racks 102. Three computer racks 102 are illustrated, but any number of computer racks can be employed. Each computer rack 102 physically holds multiple computers 104. Power distribution units (PDUs) 106 generate or transform power feeds (e.g., power) for the computers 104 in the racks 102. Each PDU 106 includes a signal injection device 108 that adds a unique signal to the power generated by that PDU. Power from individual PDUs is distributed or carried toward the racks 102 by dedicated buses 110. In the illustrated configuration, the buses 110 run above the racks 102, but other configurations, such as under the racks are contemplated.

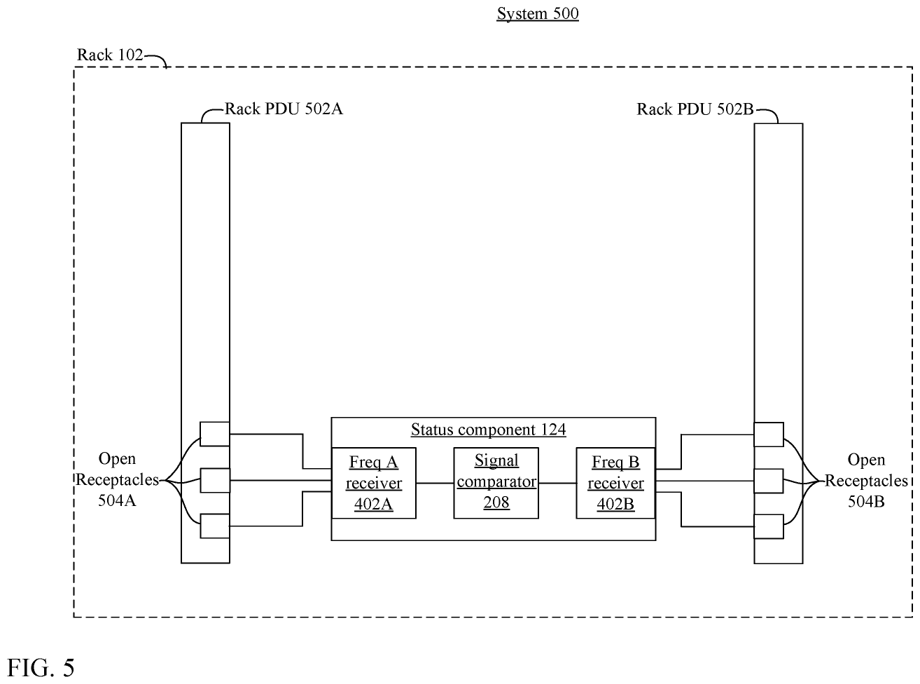

The buses 110 include tap box outlets (outlets) 112. Conductors in the form of whips or leads 114 removably connect the buses to the racks 102. Specifically, the leads 114 extend between connectors 116 and 118. Connectors 116 connect to the outlets 112 of the buses 110. The racks 102 include power management and distribution units (PMDUs) 120. The PMDUs interact with connectors 122 and include power status components 124. The lead's connectors 118 connect to the PMDU's connectors 122. The PMDU 120 can be viewed as a smart component that manages power distribution within the rack 102. An example system that does not include PMDUs is described below relative to FIG. 5.

FIG. 1A shows the leads 114 physically extending between the buses 110 and the racks 102. At this point, the leads 114 are not connected to the buses 110 and racks 102. Recall that two separate and redundant power feeds are designed to supply each rack 102. Thus, each rack 102 should receive power from PDU 106A and power from PDU 106B. Toward that end, leads 114A1, 114A2, and 114A3 are intended to carry power from PDU 106A to racks 102(1), 102(2), and 102(3), respectively. Leads 114B1, 114B2, and 114B3 are intended to carry power from PDU 106B to racks 102(1), 102(2), and 102(3), respectively.

FIG. 1B shows leads 114 connected to buses 110. In relation to rack 102(1), lead 114A1 is connected to bus 110A and hence PDU 106A with connector 116A1 connected to outlet 112A1. Similarly, lead 114B1 is connected to bus 110B and hence PDU 106B with connector 116B1 connected to outlet 112B1. In relation to rack 102(2), lead 114A2 is connected to bus 110A and hence PDU 106A with connector 116A2 connected to outlet 112A3. Similarly, lead 114B2 is connected to bus 110B and hence PDU 106B with connector 116B2 connected to outlet 112B3. In relation to rack 102(3) an inadvertent mistake is illustrated. Here, lead 114A3 is connected to bus 110B with connector 116A3 connected to outlet 112B4. Lead 114B3 is properly connected to bus 110B and hence PDU 106B with connector 116B3 connected to outlet 112B5. Thus, both leads 114A3 and 114B3 are inadvertently connected to bus 110B and hence PDU 106B, rather than one lead connected to one bus and the other lead connected to the other bus.

FIG. 1C shows the leads 114 connected to the racks' PMDUs 120. Specifically, in relation to rack 102(1), lead connector 118A1 is connected to connector 122A1, which is now occluded from view. Similarly, lead connector 118B1 is connected to connector 122B1, which is now occluded from view. In relation to rack 102(2), lead connector 118A2 is connected to connector 122A2, which is now occluded from view. Similarly, lead connector 118B2 is connected to connector 122B2, which is now occluded from view. In relation to rack 102(3), lead connector 118A3 is connected to connector 122A3, which is now occluded from view. Similarly, lead connector 118B3 is connected to connector 122B3, which is now occluded from view.

At this point, racks 102(1) and 102(2) are properly connected to redundant power feeds/supplies. Specifically, lead 114A1 connects rack 102(1) to bus 110A and hence PDU 106A while lead 114B1 connects rack 102(1) to bus 110B and hence PDU 106B. Similarly, lead 114A2 connects rack 102(2) to bus 110A and hence PDU 106A while lead 114B2 connects rack 102(2) to bus 110B and hence PDU 106B. In contrast, rack 102(3) is connected only to bus 110B and hence PDU 106B because both leads 114A3 and 114B3 are connected to bus 110B. The racks' power status components 124 can automatically sense the received power and distinguish redundant power of racks 102(1) and 102(2) from this anomalous condition illustrated relative to rack 102(3).

The PMDU 120 can include or be associated with the power status components 124. The power status component 124 can sense power received from each lead 114. The power status component 124 can sense for unique signals in each power supply it receives. The power status component 124 can then compare any sensed signals. A scenario where the status component senses a first unique signal in a first received power feed and a second different unique signal in a second received power feed indicates power supply redundancy to the rack as designed/intended. A scenario where the status component senses the same unique signal in both power feeds indicates non-compliance with the designed redundancy. The status component can then generate an indication relating to the received power supply. An example of such an indication is shown in FIG. 1D.

FIG. 1D shows the power status components 124 generating indications of the power feeds being received at their respective racks 102. In this case, relative to rack 102(1), power status component 124(1) detects a first unique signal in the power received from PDU 106A via bus 110A and lead 114A1 and a second unique signal in the power received from PDU 106B via bus 110B and lead 114B1. Accordingly, power status component 124(1) provides an indication (e.g., a ‘good’ or ‘compliant’ status indication) in the form of a light signal represented by the starburst of light emitted from the lower section of the power status component 124(1). The good status indicator indicates that the received power supplies are redundant.

Similarly, relative to rack 102(2), power status component 124(2) detects a first unique signal in the power received from PDU 106A via bus 110A and lead 114A2 and a second unique signal in the power received from PDU 106B via bus 110B and lead 114B2. Accordingly, power status component 124(2) provides a good/compliant indication in the form of a light signal represented by the starburst of light emitted from the lower section of the power status component 124(2), which is similar to the status indicated by power status component 124(1) of rack 102(1).

In contrast, relative to rack 102(3), power status component 124(3) detects a unique signal in the power received from PDU 106B via bus 110B and lead 114A3 and the same unique signal in the power received from PDU 106B via bus 110B and lead 114B3. In this case, the power status component 124(3) provides a different indication (e.g., a ‘bad’ or ‘non-compliant’ status indication) in the form of a different light signal represented by the starburst of light emitted from the upper section of the power status component 124(1). The bad status indicator indicates that the received power supplies are not redundant. Many different types of indications are contemplated. In this example, the indication is visible. Alternatively or additionally, the indication could be audible. For instance, the good indication could be ‘silence’ (e.g., no audible signal) or a pleasant tone while the bad indication is an alarm sound. In relation to visual signals, positional distinction is utilized to convey different messages (e.g., lower light is good and upper light is bad). Alternatively or additionally, other visual indicators can be utilized. For instance, a good signal can be a steady green light and a bad signal can be a blinking red light, for example. Alternatively or additionally, while this example shows the indication locally on the rack, the indication could be provided remotely, such as on a master control user interface (UI) for the system. Further, the indication could be sent to remote devices for presentation, such as the technician's and/or manager's smart phone, for example.

By design, to achieve power redundancy, each rack 102 should receive power from two different PDUs 106. That way, if an individual PDU goes offline, the rack's computers can still operate on power from the other PDU 106. To accomplish this, a first individual lead should connect an individual rack to the first bus and hence the first PDU and a second individual lead should connect the individual rack to the second bus and hence the second PDU. However, in traditional systems mistakes can prevent this designed redundancy from being achieved. The present concepts solve this technical problem by automatically detecting mistakes so that they can be remedied.

FIG. 1E shows system 100 after a technician or other user received the indication of a bad power condition on rack 102(3) as discussed relative to FIG. 1D. The technician switched connector 116A3 from outlet 112B4 of bus 110B to outlet 112A4 of bus 110A. Thus, lead 114A3 is now receiving power from PDU 106A via bus 110A. The PMDU 120(3) of rack 102(3) is receiving power from PDU 106A on lead 114A3 and power from PDU 106B on lead 114B3. The power status component 124(3) senses these two power supplies have different unique signals. The power status component 124(3) changes the indication from a bad indication as seen in FIG. 1D to a good indication as seen in FIG. 1E. This solution increases the percentage of time that computers 104 in the racks 102 remain functionally ready because they are supplied with redundant power and do not go down if power is interrupted from either PDU 106A or PDU 106B.

To summarize some of the aspects introduced above, misconnection of rack power leads such that both power leads are connected to the same bus rather than each lead to a separate bus creates a non-redundant condition at the rack. With the non-redundant condition, if either an electrical maintenance event is undertaken or a failure of one of the power sources occurs, power to the rack or a portion of the rack is lost, creating a customer impacting outage. Traditionally, verification of proper wiring requires human interaction via visual inspection and/or testing which has shown to be less than 100% reliable. The present concepts provide a technical solution that eliminates the need for human interaction. These concepts include a different unique signal via each of the power sources at the data center level. Detecting which unique signals are received at the rack can indicate which power feeds are supplying the rack. This is accomplished automatically without human intervention.

To summarize some of the other aspects, status components 124 are positioned in the rack 102 and receive power from the first and second leads 114 to power the multiple computers in the rack. The status components 124 are configured to compare power received from the first lead and power received from the second lead to determine whether the first lead and the second lead are supplying power from two different power sources or from a single power source. In other configurations, the status components or a portion thereof could be positioned remotely (e.g., outside of the racks).

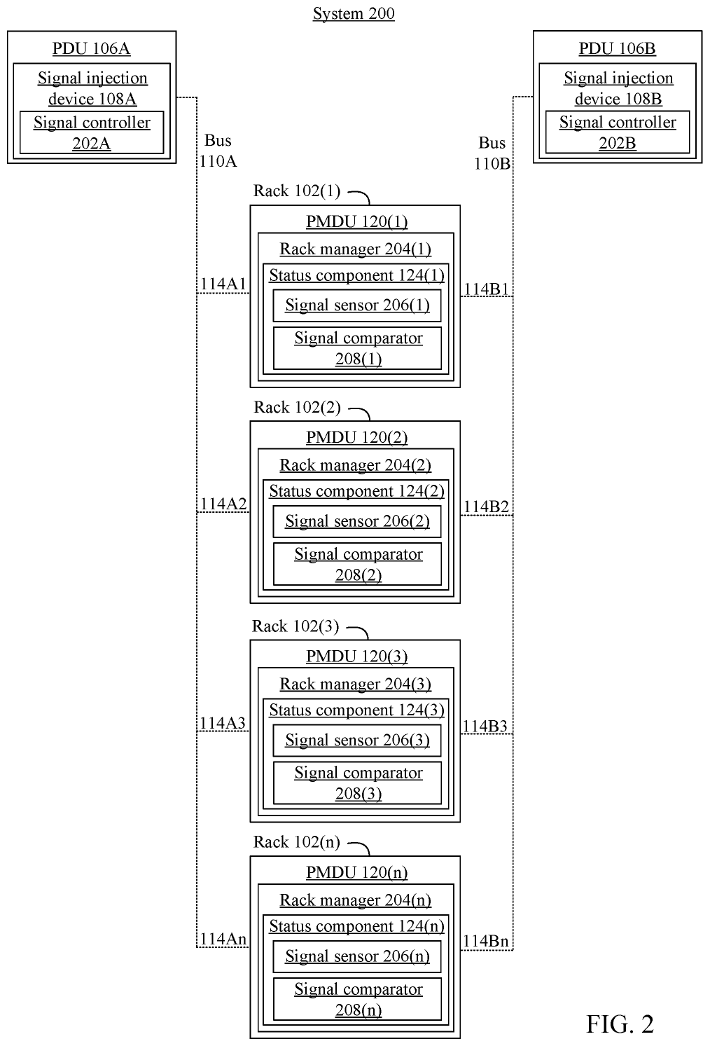

FIG. 2 shows another system 200. This system includes redundant PDUs 106A and 106B that can power any number of racks 102 (represented here as rack 102(1)-102(n)). (The suffix ‘n’ is used to convey that other numbers of racks and/or components can be employed). Individual PDUs 106 include transformers and/or other components for outputting power having desired characteristics (e.g., voltage, amperage, frequency, etc.). For instance, in one example, the power characteristics are 240 volts and 60 hertz.

The PDUs 106 include signal injection devices 108. The signal injection devices 108 include or communicate with signal controllers 202. The signal injection devices 108 are configured to generate unique electrical signals having different properties or characteristics from the power generated by the PDU 106. For instance, in one example the electrical signals have a frequency in the megahertz range compared to the 60 hertz range of the power. Recall that each signal injection device generates an electrical signal that is unique (e.g., different) from the other signal injection devices. For instance, in one example signal injection device 108A generates a signal with a frequency of 1 megahertz while signal injection device 108B generates a signal with a frequency of at least 10 megahertz, such as 100 megahertz. This is only one example, the signals can be unique in various aspects, such as waveshape, frequency, steady versus periodic, etc.

Each of the signal injection devices 108 insert their unique signal into their respective power feed generated by the respective PDU 106. Thus, power from PDU 106A includes a signal that is unique when compared to power from PDU 106B. The power from each PDU is distributed via buses 110 and leads 114. This aspect is described in detail above and is not revisited here.

In some implementations, the signal controller 202 controls properties of the unique signal that is generated by the signal injection device 108 (e.g., signal generator). In other configurations, the properties are hard coded/wired at the time of manufacture and are not adjustable. In some implementations, the signal controller 202 can communicate with other devices, such as to convey information about the properties of the unique signal and/or to receive values for the properties, such as from a remote device.

At the individual racks 102, rack managers 204 receive power from the buses 110 and leads 114 and distributes the power to the computers (104, FIG. 1A) of the rack. The rack managers 204 include power status components 124. The individual power status components 124 evaluate the power received by the PMDU 120 at the individual rack. The power status component 124 generates an indication of whether or not redundant (e.g., different) power supplies are being received at the rack. In this example, the power status components 124 include signal sensors 206 and signal comparators 208.

The signal sensors 206 attempt to detect unique signals in the received power. For instance, the signal sensors can scan through a range of frequencies looking for the presence of signals. For example, given that the power supply is at 60 hertz in many configurations, the signal sensors may scan above 60 hertz, such as starting at 1000 hertz and scanning higher. The signal sensors 206 examine the received power supplies and provide any identified unique signals to the signal comparator 208. In the illustrated configuration with two power supplies, the signal sensor should detect a ‘unique’ signal in each power supply. A power supply without a unique signal would indicate a malfunction or fault condition associated with the respective signal injection device 108 (e.g., the signal injection is broken or not connected). The signal sensor sends detected unique signals (or information about the unique signals, such as frequency) to the signal comparator 208.

The signal comparator 208 compares the received unique signals to determine if they are the same ‘unique’ signal or different ‘unique’ signals. This comparison can be done in various ways. For instance, the comparison can entail subtracting one unique signal from the other unique signal. A non-zero result indicates that each of the signals is in fact unique. This is the desired configuration in that the rack is receiving two different power supplies. A zero result indicates the rack is receiving the same power supply twice and thus there is no redundancy. The signal comparator 208 can take an action, such as provide an indication based upon the results of the comparison. In the example illustrated relative to FIGS. 1A-1E, the indication related to a status light (e.g., green light for two unique signals indicating redundant power supplies or red light for less than two unique signals). Thus, the condition where a received power supply did not receive a unique signal could be indicated with a red indicator. In this later configuration, a red indicator represents any condition other than a redundant condition.

Alternatively or additionally, the signal comparator 208 communicates with other devices. The communication can include incoming communications, such as parameter information to tune the signal sensor 206. The communication can also include outgoing communications from the signal comparator 208, such as the indication regarding power supply redundancy or lack thereof.

To summarize some aspects, the PMDUs 106 can entail signal sensors 206 and signal comparators 208. The signal sensors 206 can be configured to detect unique signals in the power received at the first and second electrical connectors (122(1) and 122(2) of FIG. 1A). The signal comparators 208 are configured to determine whether the detected unique signals are the same or different from one another.

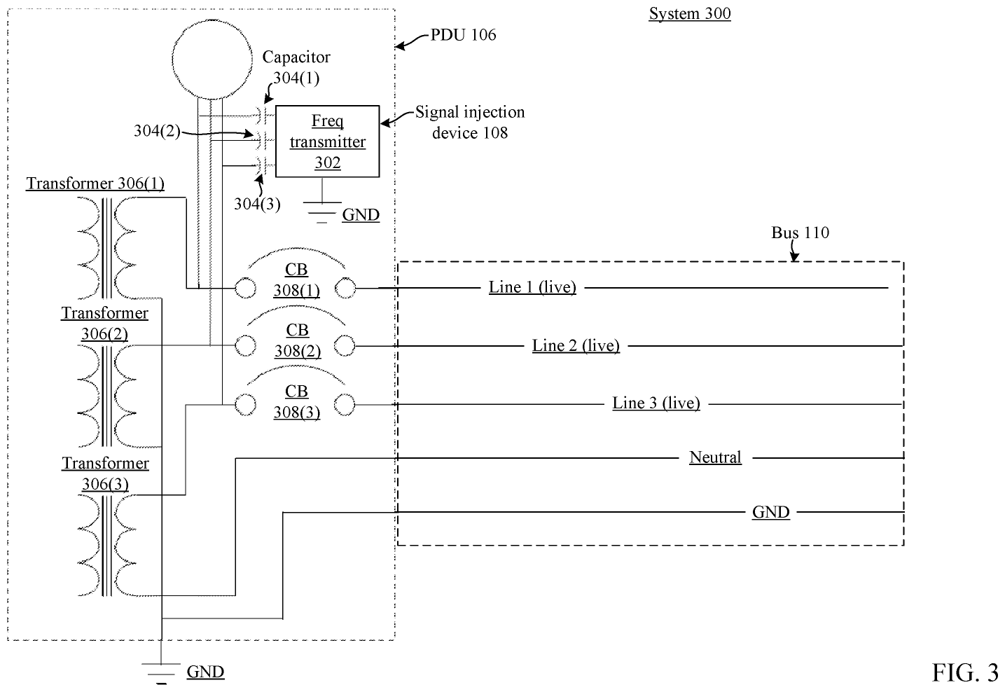

FIG. 3 shows a schematic diagram of an example system 300 for implementing an example PDU 106 configuration. In this implementation, the signal injection device 108 is manifest as a frequency transmitter 302. This implementation also includes three capacitors 304, three transformers 306, and three circuit breakers 308. This example provides a five-line three-phase bus 110 that includes three positive or live lines (e.g., lines 1-3) a neutral line, and a ground (GND) line.

The transformers 306 are oriented on the drawing page with the source on the left and supply on the right. The supply side of transformer 306(1) is connected to the input side of circuit breaker 308(1) and to ground. The frequency transmitter 302 is connected to ground. The output of the frequency transmitter 302 is connected to the positive side of capacitor 304(1). The negative side of capacitor 304(1) is connected to the input side of circuit breaker 306(1). Thus, the output of the frequency transmitter is added to the power feed from transformer 306(1) that is supplied to circuit breaker 308(1). The output side of circuit break 308(1) is connected to supply line 1, which is a live or positive line.

Similarly, the supply side of transformer 306(2) is connected to the input side of circuit breaker 308(2) and to ground. The output of the frequency transmitter 302 is connected to the positive side of capacitor 304(2). The negative side of capacitor 304(2) is connected to the input side of circuit breaker 306(2). Thus, the output of the frequency transmitter is added to the power feed from transformer 306(2) that is supplied to circuit breaker 308(2). The output side of circuit break 308(2) is connected to supply line 2, which is a live or positive line.

The supply side of transformer 306(3) is connected to the input side of circuit breaker 308(3) and to the neutral line. The output of the frequency transmitter 302 is connected to the positive side of capacitor 304(3). The negative side of capacitor 304(3) is connected to the input side of circuit breaker 306(3). Thus, the output of the frequency transmitter is added to the power feed from transformer 306(3) that is supplied to circuit breaker 308(3). The output side of circuit breaker 308(3) is connected to supply line 3, which is a live or positive line.

In this implementation, the frequency transmitter generates a unique signal that is added to the power feeds from the transformers 306. Any unique signal can be employed that is readily distinguishable from the power feed (signal). For instance, the unique signal can be a sine wave or rectified wave having a frequency that is an order of magnitude higher than the frequency of the power feed. The frequency transmitter 302 may have a fixed (e.g., non-adjustable) output signal. In other configurations, the frequency transmitter may be set (e.g., adjusted) to produce a desired unique signal. In the configuration described above relative to FIG. 2, the signal controller 202 could control the unique signal produced by the signal injection device 108. Recall, in the implementation of FIG. 3, the signal injection device 108 is the frequency transmitter 302.

The configuration shown here can be replicated for the other (e.g., redundant power feed) except that a different unique signal will be generated to facilitate distinguishing the two power feeds.

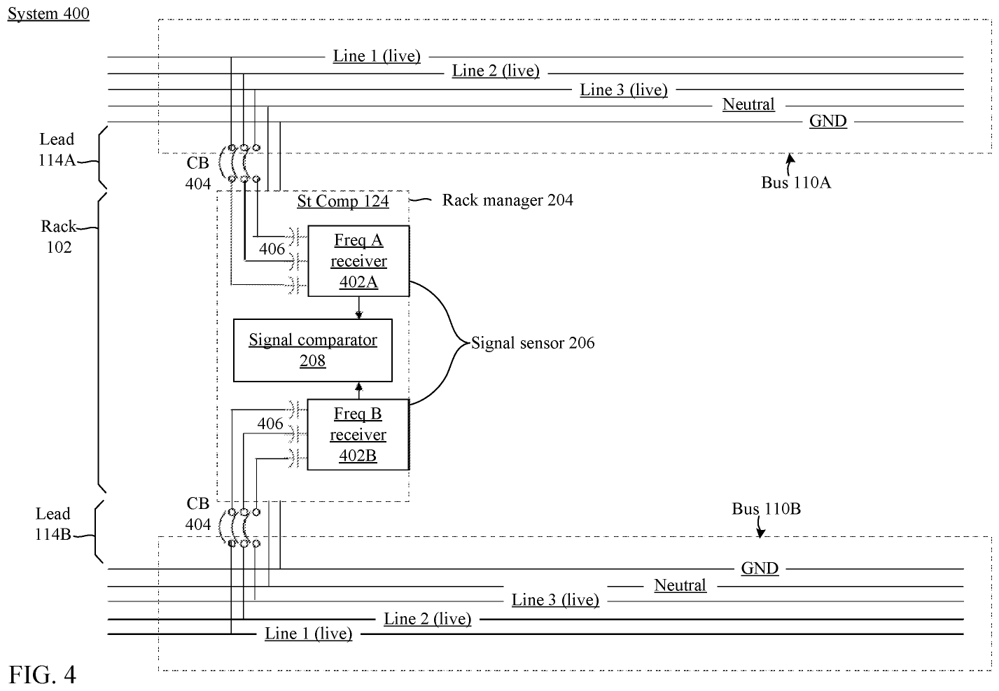

FIG. 4 shows a schematic diagram of an example system 400 for implementing PMDU 120 and rack manager 204. The rack manager can include status components 124 or perform functionalities described for the status components. Recall that in some versions, the status components 124 include signal sensors 206 and signal comparators 208. In this case, the signal sensors 206 are manifest as frequency receivers 402 dedicated to each lead 114.

Circuit breakers 404 positioned relative to the leads 114 protect the rack 102 from power surges. Individual circuit breakers 404 receive each of the live lines of the leads 114. The live leads terminate at negative sides of capacitors 406. The positive sides of the capacitors are connected to the frequency receivers 402. Thus, in this implementation, the rack manager 204 has connections to all phases, neutral, and ground from both of the bus power feeds. The frequency receivers are tuned to specific frequencies (as determined by the frequency transmitters 302 of FIG. 3). Stated another way, frequency A receiver 402A is tuned to detect the unique signal (e.g., frequency) added to power feed A by signal injection device 108A and frequency B receiver 402B is tuned to detect the unique signal (e.g., frequency) added to power feed B by signal injection device 108B. Alternatively, the frequency receivers 402 can scan a range of frequencies, such as 1 megahertz to 100 megahertz, for example, within which the injected unique frequencies reside). The signal comparator 208 can be manifest as a logic device that receives the frequency sensed by each of the frequency receivers 404. The signal comparator 208 can compare the received frequencies to determine redundancy or lack of redundancy.

To summarize some of the concepts explained above, in some implementations, the rack managers 204 sample all three phases of each power feed. The rack managers 204 can detect the unique signal on each power feed (or even each of the six phases) and then compare the unique signals to ensure that different feeds were applied to each of the lead connections to the rack. Some implementations provide a technical solution that includes additional functionality to allow auto checking for rotating phases or feeds for load balancing. The technical solution can entail a simple high frequency carrier connected to each feed/phase and then detected via a narrow band pass filter in each rack. Once the frequencies are determined, ‘exclusive OR’ (XOR) logic is applied to verify that that the proper power feeds were connected to each of the whips/phases.

To summarize other aspects, the rack managers 204 can be configured, such as via the status component 124, to sense individual power supplies received at the rack for the presence of unique signals. The rack managers 204 are configured so that upon sensing the first unique signal in a first received individual power supply and the second unique signal in a second received individual power supply, the rack manager generates a first status indicator and otherwise generates a second different status indicator.

FIG. 5 shows another system 500. In this configuration, the status component 124 is configured to provide power management functionality to the computers 104 of the rack 102. This implementation does not employ PMDUs, and instead employs rack power distribution units (rack PDUs) 502 that lack some or all of the power management functionality performed by the PMDUs. The status component 124 is plugged into open receptacles 504 in the rack PDUs (e.g., receptacles that are not occupied by rack computers or other devices). Power from rack PDU 502A is fed to frequency A receiver 402A (e.g., the frequency of the unique signal added to power feed A) and power from rack PDU 502B is fed to frequency B receiver 402B (e.g., the frequency of the unique signal added to power feed B). Alternatively, each of the frequency receivers can scan a range of frequencies that contains the frequencies of the injected unique signals. Note that for simplicity sake frequencies of the unique signals are discussed, but other properties of the unique signals can be detected alternatively or additionally to frequency.

The frequency receivers 402 send their results to the signal comparator 208. The signal comparator 208 can determine if the two power feeds (e.g., the power feed received at rack PDU 502A and rack PDU 502B) are from the same or different power sources based on equivalent frequencies or lack thereof in the compared received frequencies.

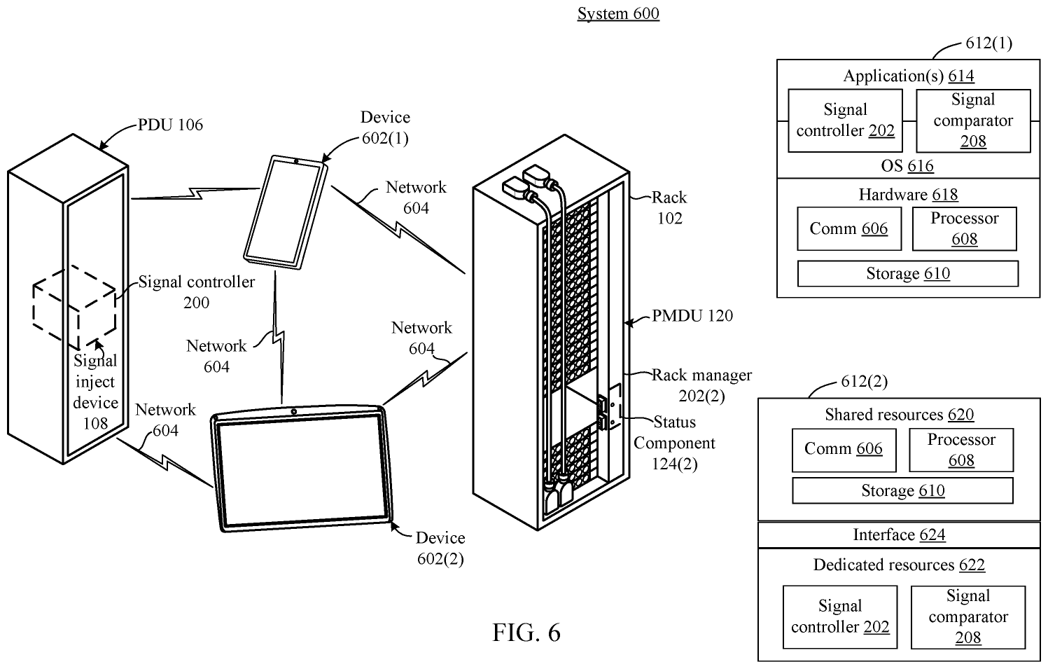

FIG. 6 shows another example system 600 that is similar to system 100 introduced relative to FIG. 1A. System 600 can include computer devices 602, as well as PDUs 106 and racks 102. In the illustrated configuration, device 602(1) is manifest as a smartphone and device 602(2) is manifest as a tablet type device. Similarly, the signal injection device 108 of PDU 106 and PMDU 120 of rack 102 can be viewed as devices. These devices can be coupled via a network 604 that is represented by lightning bolts.

The devices 602, signal injection device 108, and PMDU 120 can include a communication component 606, a processor 608, storage 610, and an instance of signal controller 202 or signal comparator 208.

FIG. 6 shows two device configurations 612 that can be employed by devices 602, signal injection device 108, and/or PMDU 120. Individual devices can employ either of configurations 612(1) or 612(2), or an alternate configuration. (Due to space constraints on the drawing page, one instance of each configuration is illustrated). Briefly, device configuration 612(1) represents an operating system (OS) centric configuration. Device configuration 612(2) represents a system on a chip (SOC) configuration. Device configuration 612(1) is organized into one or more applications 614, operating system 616, and hardware 618. Device configuration 612(2) is organized into shared resources 620, dedicated resources 622, and an interface 624 therebetween.

In configuration 612(1), the signal controller 202 or signal comparator 208 can be manifest as part of the processor 608. Alternatively, the signal controller 202 or signal comparator 208 can be manifest as part of the operating system 616. Further still, the signal controller 202 or signal comparator 208 can be a freestanding component, such as part of hardware 618 that operates cooperatively with the operating system 616 and/or the processor 608 (e.g., as a freestanding service that works cooperatively with the applications and the operating system). For instance, the frequency transmitters (302, FIG. 3) and/or the frequency receivers (402, FIG. 4) can be hardware 618, while other components are hardware or software, for example.

In configuration 612(2), the signal controller 202 or signal comparator 208 can be manifest as part of the processor 608 or as a dedicated resource 622 that operates cooperatively with the processor 608. In some cases, the frequency receivers of FIG. 4 can be dedicated resources, while the signal comparator 208 can be shared or dedicated resources, for example.

In some configurations, each of devices 602, signal injection device 108, and PMDU 120 can have an instance of the signal controller 202 or signal comparator 208. However, the functionalities that can be performed by the signal controller 202 or signal comparator 208 may be the same or they may be different from one another when comparing devices. For instance, in some cases, each signal controller 202 or signal comparator 208 can be robust and provide all of the functionality described above and below (e.g., a device-centric implementation). In other cases, some devices can employ a less robust instance of the signal controller 202 or signal comparator 208 that relies on some functionality to be performed by another device.

The term “device,” “computer,” or “computing device” as used herein can mean any type of device that has some amount of processing capability and/or storage capability. Processing capability can be provided by one or more processors that can execute data in the form of computer-readable instructions to provide a functionality. Data, such as computer-readable instructions and/or user-related data, can be stored on storage, such as storage that can be internal or external to the device. The storage can include any one or more of volatile or non-volatile memory, hard drives, flash storage devices, and/or optical storage devices (e.g., CDs, DVDs, etc.), remote storage (e.g., cloud-based storage), among others. As used herein, the term “computer-readable media” can include signals. In contrast, the term “computer-readable storage media” excludes signals. Computer-readable storage media includes “computer-readable storage devices.” Examples of computer-readable storage devices include volatile storage media, such as RAM, and non-volatile storage media, such as hard drives, optical discs, and flash memory, among others.

As mentioned above, device configuration 612(2) can be thought of as a system on a chip (SOC) type design. In such a case, functionality provided by the device can be integrated on a single SOC or multiple coupled SOCs. One or more processors 608 can be configured to coordinate with shared resources 620, such as storage 610, etc., and/or one or more dedicated resources 622, such as hardware blocks configured to perform certain specific functionality. Thus, the term “processor” as used relative to FIG. 6 can also refer to central processing units (CPUs), graphical processing units (GPUs), field programable gate arrays (FPGAs), controllers, microcontrollers, processor cores, or other types of processing devices.

Generally, any of the functions described herein can be implemented using software, firmware, hardware (e.g., fixed-logic circuitry), or a combination of these implementations. The term “component” as used herein generally represents software, firmware, hardware, whole devices or networks, or a combination thereof. In the case of a software implementation, for instance, these may represent program code that performs specified tasks when executed on a processor (e.g., CPU or CPUs). The program code can be stored in one or more computer-readable memory devices, such as computer-readable storage media. The features and techniques of the component are platform-independent, meaning that they may be implemented on a variety of commercial computing platforms having a variety of processing configurations.

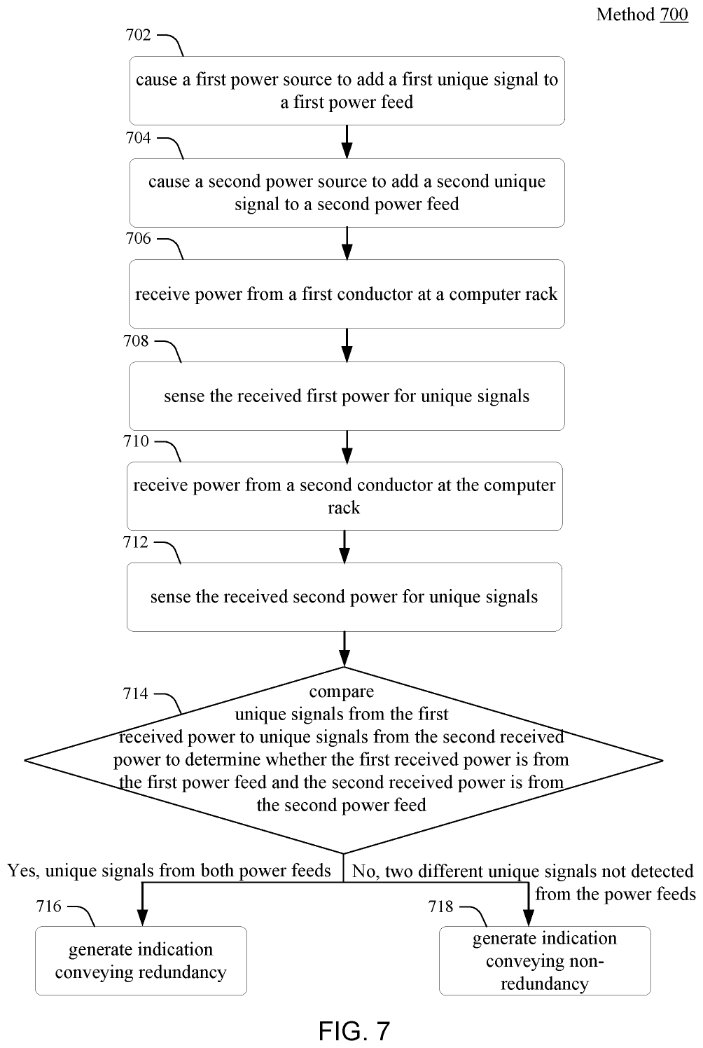

FIG. 7 shows an example method or technique 700 relating to evaluating power feed redundancy.

Block 702 can cause a first power source to add a first unique signal to a first power feed.

Block 704 can cause a second power source to add a second unique signal to a second power feed.

Block 706 can receive power from a first conductor (e.g., line or connector) at a computer rack.

Block 708 can sense the received first power for unique signals.

Block 710 can receive power from a second conductor (e.g., line or connector) at the computer rack.

Block 712 can sense the received second power for unique signals.

Block 714 can compare unique signals from the first received power to unique signals from the second received power to determine whether the first received power is from the first power feed and the second received power is from the second power feed.

Stated another way, this comparison can distinguish a ‘good’ (e.g., redundant) condition from a ‘bad’ (e.g., non-redundant) condition. The good condition confirms that power is being received from two different power supplies to achieve power supply redundancy. In contrast, the comparison identifies bad conditions where a unique signal is detected on the first received power feed, but no unique signal is detected on the second received power feed, or no unique signal is detected on the first received power feed, but a unique signal is detected on the second received power feed, or no unique signal is detected on either received power feed, or the same unique signal is detected on both the first and second power feeds.

A ‘yes’ condition (e.g., unique (and different) signals from both feeds) proceeds to block 716. Block 716 generates an indication conveying power feed redundancy.

A ‘no’ condition (e.g., not detecting two different unique signals from power feeds) proceeds to block 718. Block 718 generates an indication conveying non-redundancy.

The order in which the disclosed methods are described is not intended to be construed as a limitation, and any number of the described acts can be combined in any order to implement the method, or an alternate method. Furthermore, the methods can be implemented in any suitable hardware, software, firmware, or combination thereof, such that a computing device can implement the method. In one case, the methods are stored on one or more computer-readable storage media as a set of instructions such that execution by a processor of a computing device causes the computing device to perform the method.

### Additional Examples

Various examples are described above. Additional examples are described below. One example includes a system comprising a first power distribution unit configured to generate a first power supply to power computers in a rack and to insert a first unique signal in the first power supply, a second power distribution unit configured to generate a second power supply to power the computers in the rack and to insert a second unique signal in the second power supply, and a rack manager positioned in the rack and connected to the computers, the rack manager configured to sense individual power supplies received at the rack for the presence of unique signals and upon sensing the first unique signal in a first received individual power supply and the second unique signal in a second received individual power supply the rack manager is configured to generate a first status indicator and to otherwise generate a second different status indicator.

Another example can include any of the above and/or below examples where the first power supply and the second power supply comprise 240 volt and 60 hertz signals and wherein the first unique signal comprises a frequency range of 1 megahertz to 5 megahertz and the second unique signal comprises a frequency of at least 10 megahertz.

Another example can include any of the above and/or below examples where the first status indicator comprises a first audible indicator and the second status indicator comprises a second different audible indicator, or wherein the first status indicator comprises a first visual indicator and the second status indicator comprises a second different visual indicator.

Another example can include any of the above and/or below examples where the first status indicator and the second status indicator are generated on a user interface that is accessible from a remote device.

Another example can include any of the above and/or below examples where the rack manager comprises a signal sensor configured to sense individual power supplies received at the rack for the presence of unique signals.

Another example can include any of the above and/or below examples where the signal sensor comprises a frequency receiver.

Another example can include any of the above and/or below examples where the frequency receiver is tuned to a specific frequency, or wherein the frequency receiver is tunable, or wherein the frequency receiver is tuned to a frequency range.

Another example can include any of the above and/or below examples where the rack manager comprises a signal comparator configured to compare unique signals sensed by the signal sensor.

Another example can include any of the above and/or below examples where the first power distribution unit includes a first signal injection device configured to generate the first unique signal, and wherein the second power distribution unit includes a second signal injection device configured to generate the second unique signal.

Another example can include any of the above and/or below examples where the system further comprises a first bus connected to the first power distribution unit and a second bus connected to the second power distribution unit.

Another example can include any of the above and/or below examples where the system further comprises a first lead removably connected between a connector on the first bus and a connector on the rack and a second lead removably connected between a connector on the second bus and another connector on the rack.

Another example includes a system comprising a first signal injection device configured to insert a first unique signal in a first power supply, a second signal injection device configured to insert a second different unique signal in a second power supply, and a rack physically holding multiple computers, the rack comprising a power management and distribution unit (PMDU) receiving power at first and second electrical connectors; the PMDU comprising a signal sensor configured to detect unique signals in the power received at the first and second electrical connectors, and a signal comparator configured to determine whether the detected unique signals are the same or different from one another.

Another example can include any of the above and/or below examples where the signal sensor is tuned to detect parameters of the first and second unique signals.

Another example can include any of the above and/or below examples where the parameters include frequencies of the first and second unique signals.

Another example can include any of the above and/or below examples where the signal sensor is configured to scan to detect parameters of the first and second unique signals.

Another example can include any of the above and/or below examples where the signal comparator is further configured to determine whether the rack is receiving power from two different power feeds based upon the detected unique signals.

Another example can include any of the above and/or below examples where the signal comparator is further configured to generate an indication that conveys whether the rack is receiving power from two different power feeds.

Another example can include any of the above and/or below examples where the signal comparator is further configured to present the indication at the rack and/or to send the indication to a remote device.

Another example includes a system comprising a rack holding multiple computers, first and second leads connected to the rack, and a status component positioned in the rack and receiving power from the first and second leads to power the multiple computers, the status component configured to compare power received from the first lead and power received from the second lead to determine whether the first lead and the second lead are supplying power from two different power sources or from a single power source.

Another example can include any of the above and/or below examples where the status component is configured to detect unique signals in the power from the first and second leads and to compare the unique signals to determine whether the first lead and the second lead are supplying power from two different power sources or from a single power source.

Another example includes a method comprising causing a first power source to add a first unique signal to a first power feed, causing a second power source to add a second unique signal to a second power feed, receiving power from a first conductor at a computer rack, sensing the received first power for unique signals, receiving power from a second conductor at the computer rack, sensing the received second power for unique signals, and comparing unique signals from the first received power to unique signals from the second received power to determine whether the first received power is from the first power feed and the second received power is from the second power feed.

### CONCLUSION

Although the subject matter relating to increasing reliability of rack computers by ensuring power feed redundancy has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A system, comprising:
a first power distribution unit configured to generate a first power supply to power computers in a rack and to insert a first unique signal in the first power supply;
a second power distribution unit configured to generate a second power supply to power the computers in the rack and to insert a second unique signal in the second power supply; and,
a rack manager positioned in the rack and connected to the computers, the rack manager configured to sense individual power supplies received at the rack for the presence of unique signals and upon sensing the first unique signal in a first received individual power supply and the second unique signal in a second received individual power supply the rack manager is configured to generate a first status indicator and to otherwise generate a second different status indicator.

2. The system of claim 1, wherein the first power supply and the second power supply comprise 240 volt and 60 hertz signals and wherein the first unique signal comprises a frequency range of 1 megahertz to 5 megahertz and the second unique signal comprises a frequency of at least 10 megahertz.

3. The system of claim 1, wherein the first status indicator comprises a first audible indicator and the second status indicator comprises a second different audible indicator, or wherein the first status indicator comprises a first visual indicator and the second status indicator comprises a second different visual indicator.

4. The system of claim 1, wherein the first status indicator and the second status indicator are generated on a user interface that is accessible from a remote device.

5. The system of claim 1, wherein the rack manager comprises a signal sensor configured to sense individual power supplies received at the rack for the presence of unique signals.

6. The system of claim 5, wherein the signal sensor comprises a frequency receiver.

7. The system of claim 6, wherein the frequency receiver is tuned to a specific frequency, or wherein the frequency receiver is tunable, or wherein the frequency receiver is tuned to a frequency range.

8. The system of claim 5, wherein the rack manager comprises a signal comparator configured to compare unique signals sensed by the signal sensor.

9. The system of claim 1, wherein the first power distribution unit includes a first signal injection device configured to generate the first unique signal, and wherein the second power distribution unit includes a second signal injection device configured to generate the second unique signal.

10. The system of claim 1 further comprising a first bus connected to the first power distribution unit and a second bus connected to the second power distribution unit.

11. The system of claim 10, further comprising a first lead removably connected between a connector on the first bus and a connector on the rack and a second lead removably connected between a connector on the second bus and another connector on the rack.

12. A system, comprising:
a first signal injection device configured to insert a first unique signal in a first power supply;
a second signal injection device configured to insert a second different unique signal in a second power supply; and,
a rack physically holding multiple computers, the rack comprising a power management and distribution unit (PMDU) receiving power at first and second electrical connectors; the PMDU comprising a signal sensor configured to detect unique signals in the power received at the first and second electrical connectors, and a signal comparator configured to determine whether the detected unique signals are the same or different from one another.

13. The system of claim 12, wherein the signal sensor is tuned to detect parameters of the first and second unique signals.

14. The system of claim 13, wherein the parameters include frequencies of the first and second unique signals.

15. The system of claim 12, wherein the signal sensor is configured to scan to detect parameters of the first and second unique signals.

16. The system of claim 12, wherein the signal comparator is further configured to determine whether the rack is receiving power from two different power feeds based upon the detected unique signals.

17. The system of claim 16, wherein the signal comparator is further configured to generate an indication that conveys whether the rack is receiving power from two different power feeds.

18. The system of claim 17, wherein the signal comparator is further configured to present the indication at the rack and/or to send the indication to a remote device.

19. A system, comprising:
a rack holding multiple computers;
first and second leads connected to the rack; and,
a status component positioned in the rack and receiving power from the first and second leads to power the multiple computers, the status component configured to compare power received from the first lead and power received from the second lead to determine whether the first lead and the second lead are supplying power from two different power sources or from a single power source.

20. The system of claim 19, wherein the status component is configured to detect unique signals in the power from the first and second leads and to compare the unique signals to determine whether the first lead and the second lead are supplying power from two different power sources or from a single power source.
